(19) United States
(12) Patent Application Publication
(10) Pub. No.: US 2026/0262515 A1
(43) Pub. Date: Sep. 3, 2026

(54) ELECTRONIC DEVICE

(71) Applicant: Advanced Semiconductor Engineering, Inc., Kaohsiung (TW)

(72) Inventors: Cheng-Yuan KUNG, Kaohsiung (TW); Hung-Yi LIN, Kaohsiung (TW)

(73) Assignee: Advanced Semiconductor Engineering, Inc., Kaohsiung (TW)

(21) Appl. No.: 19/653,006

(22) Filed: Apr. 20, 2026

Related U.S. Application Data
(63) Continuation of application No. 17/460,057, filed on Aug. 27, 2021, now abandoned.

(51) Int. Cl. H10W 70/63; H10W 20/20; H10W 20/42; H10W 72/00; H10W 72/20; H10W 74/10

(52) U.S. Cl. CPC H10W 70/635; H10W 20/20; H10W 20/42; H10W 74/117; H10W 72/07253; H10W 72/232

(57) ABSTRACT

An electronic device includes a first electronic component, an encapsulant and a second electronic component. The encapsulant encapsulates the first electronic component. The second electronic component is disposed over the first electronic component and separated from the encapsulant. The second electronic component is configured to receive a power from the first electronic component.

### CROSS REFERENCE TO RELATED APPLICATION

This application is a continuation of U.S. patent application Ser. No. 17/460,057, filed Aug. 27, 2021, the content of which is incorporated herein by reference in its entirety.

### BACKGROUND

### 1. Field of the Disclosure

The present disclosure relates to an electronic device, and to an electronic device including at least two electronic components.

### 2. Description of the Related Art

In a fan-in package structure, a through silicon via may be formed through a semiconductor die for electrical connection between components disposed on two opposite surfaces of the semiconductor die. However, the fan-in package cannot meet the requirement of some products which need high input/output (I/O) count.

### SUMMARY

In some embodiments, an electronic device includes a first electronic component, an encapsulant and a second electronic component. The encapsulant encapsulates the first electronic component. The second electronic component is disposed over the first electronic component and separated from the encapsulant. The second electronic component is configured to receive a power from the first electronic component.

In some embodiments, an electronic device includes a first electronic component, conductive element and a second electronic component. The conductive element is disposed adjacent to the first electronic component. The second electronic component covers the first electronic component and is physically separated from the conductive element. The second electronic component is electrically connected to the conductive element and configured to receive a power from the first electronic component.

In some embodiments, an electronic device includes a first wiring structure, a first electronic component, at least one conductive element and a second electronic component. The first electronic component is disposed on the first wiring structure and includes at least one interconnection element. The conductive element is disposed on the first wiring structure. The second electronic component is disposed over the first electronic component, and is electrically connected to the first wiring structure through the first electronic component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross sectional view of an electronic device according to some embodiments of the present disclosure.

FIG. 2 illustrates a cross sectional view of an electronic device according to some embodiments of the present disclosure.

FIG. 3 illustrates a cross sectional view of an electronic device according to some embodiments of the present disclosure.

FIG. 4 illustrates a cross sectional view of an electronic device according to some embodiments of the present disclosure.

FIG. 5 illustrates one or more stages of an example of a method for manufacturing electronic device according to some embodiments of the present disclosure.

FIG. 6 illustrates one or more stages of an example of a method for manufacturing electronic device according to some embodiments of the present disclosure.

FIG. 7 illustrates one or more stages of an example of a method for manufacturing electronic device according to some embodiments of the present disclosure.

FIG. 8 illustrates one or more stages of an example of a method for manufacturing electronic device according to some embodiments of the present disclosure.

FIG. 9 illustrates one or more stages of an example of a method for manufacturing electronic device according to some embodiments of the present disclosure.

FIG. 10 illustrates one or more stages of an example of a method for manufacturing an electronic device according to some embodiments of the present disclosure.

FIG. 11 illustrates one or more stages of an example of a method for manufacturing an electronic device according to some embodiments of the present disclosure.

FIG. 12 illustrates one or more stages of an example of a method for manufacturing an electronic device according to some embodiments of the present disclosure.

FIG. 13 illustrates one or more stages of an example of a method for manufacturing an electronic device according to some embodiments of the present disclosure.

FIG. 14 illustrates one or more stages of an example of a method for manufacturing an electronic device according to some embodiments of the present disclosure.

FIG. 15 illustrates one or more stages of an example of a method for manufacturing an electronic device according to some embodiments of the present disclosure.

FIG. 16 illustrates one or more stages of an example of a method for manufacturing an electronic device according to some embodiments of the present disclosure.

FIG. 17 illustrates one or more stages of an example of a method for manufacturing an electronic device according to some embodiments of the present disclosure.

FIG. 18 illustrates one or more stages of an example of a method for manufacturing an electronic device according to some embodiments of the present disclosure.

FIG. 19 illustrates one or more stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In a present fan-out system-in-package (FOSiP) structure, a capacitor may be disposed on a semiconductor chip, and a plurality of conductive pillars may be formed on the semiconductor chip to surround the capacitor. Then, an encapsulant is formed on the semiconductor chip to encapsulate the capacitor and the conductive pillars, and then a redistribution layer is formed on the encapsulant to electrically connect the capacitor and the conductive pillars.

However, in the aforementioned FOSiP structure, the formation of the conductive pillars and the molding/grinding process of the encapsulant may adversely affect the yield of the semiconductor chip, and lengthen the production time of the semiconductor chip. Besides, the area of the redistribution layer is limited by the size of the semiconductor chip.

Hence, at least some embodiments of the present disclosure provide for an electronic device which does not affect the yield and production time of the semiconductor chip, and can provide a larger area for the redistribution layer.

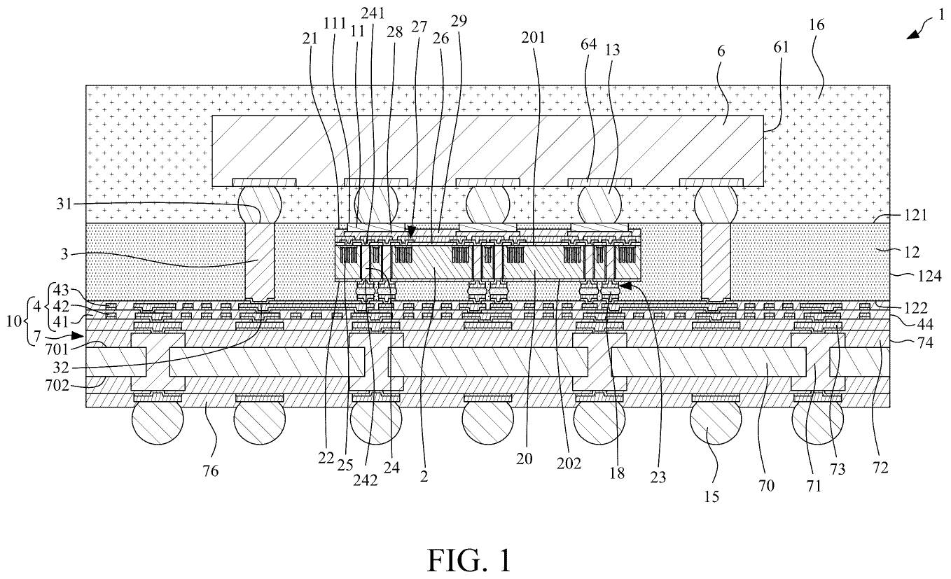

FIG. 1 illustrates a cross sectional view of an electronic device 1 according to some embodiments of the present disclosure. The electronic device 1 may include a first wiring structure 10, at least one external connecter 15, at least one first electronic component 2, at least one conductive element 3, a first encapsulant 12, at least one second electronic component 6 and a second encapsulant 16.

The first wiring structure 10 may include a first conductive structure 4 and a second conductive structure 7. In some embodiments, the first wiring structure 10 may also be referred as a second wiring structure.

The second conductive structure 7 may be a low density wiring structure. The second conductive structure 7 may include a core substrate 70, at least one through via 71, at least one dielectric layer 72, at least one circuit pattern layer 73 and a solder resist layer 76. The amount of the dielectric layers 72 and the amount of the circuit pattern layer (or may be called patterned circuit layer) 73 are not limited in the present disclosure. The core substrate 70 has a first surface 701 and a second surface 702 opposite to the first surface 701. The through via 71 extends through the core substrate 70. At least a portion of the through via 71 may extend on the first surface 701 and/or the second surface 702 of the core substrate 70. The dielectric layer 72 may be disposed on the first surface 701 of the core substrate 70 to cover the through via 71. The circuit pattern layer 73 may be disposed on and extend through the dielectric layer 72 to electrically connect the through via 71. The circuit pattern layer 73 of the second conductive structure 7 may be a low density circuit pattern layer. The circuit pattern layer 73 may include a seed layer and a conductive layer. In some embodiments, the seed layer may be omitted. The circuit pattern layer 73 may include a conductive pad and/or a conductive trace. Another dielectric layer 72 may be disposed on and cover the circuit pattern layer 73. Similarly, the dielectric layer 72 and the circuit pattern layer 73 may also disposed on the second surface 702 of the core substrate 70. The solder resist layer 76 may be disposed on the circuit pattern layer 73 adjacent to the second surface 702 of the core substrate 7 and expose a portion of the circuit pattern layer 73. The external connector 15 may be disposed on and electrically connected to the exposed portion of the circuit pattern layer 73.

The first conductive structure 4 may be a high density wiring structure. The first conductive structure 4 is disposed on and electrically connected to the second conductive structure 7. As shown in FIG. 1, the first conductive structure 4 is disposed on the dielectric layer 72 and the circuit pattern layer 73 adjacent to the first surface 701 of the core substrate 70 of the second conductive structure 7. A bottom surface of the first conductive structure 4 may contact a top surface of the second conductive structure 7. The first conductive structure 4 may include at least one dielectric layer 41, at least one circuit pattern layer (e.g., a circuit pattern layers 42 and an additional circuit pattern layer 43). However, the amount of the dielectric layer 41 and the amount of the circuit pattern layers 42, 43 are not limited in the present disclosure. The circuit pattern layer 42 may be disposed on and extend through the dielectric layer 72 of the second conductive structure 7 to electrically connect and/or contact the circuit pattern layer 73 of the second conductive structure 7. The dielectric layer 41 may be disposed on and cover the circuit pattern layer 42. The additional circuit pattern layer 43 and another dielectric layer 41 may be sequentially disposed on the circuit pattern layer 42 in a similar manner. The circuit pattern layer 42 and/or the additional circuit pattern layer 43 may include a seed layer and a conductive layer. In some embodiments, the seed layer may be omitted. The circuit pattern layer 42 and/or the additional circuit pattern layer 43 may include a conductive pad and/or a conductive trace. The circuit pattern layer 42 and/or the additional circuit pattern layer 43 may be a high density circuit pattern layer. That is, a line width/line space (L/S) of the circuit pattern layer 42 and/or the additional circuit pattern layer 43 of the first conductive structure 4 is less than a line width/line space of the circuit pattern layer 73 of the second conductive structure 7. In some embodiments, the circuit pattern layer 42 of the first conductive structure 4 may be referred as a first circuit pattern layer, and the circuit pattern layer 73 of the second conductive structure 7 may be referred as a second circuit pattern layer 7. The density of the first circuit pattern layer 42 may be greater than the density of the second circuit pattern layer 73. The term “density” of a circuit pattern layer may refer to an amount of traces or pads of the circuit pattern layer per unit area.

The first electronic component 2 is disposed on the first conductive structure 4. The first electronic component 2 may be a passive element. In some embodiments, the first electronic component 2 is configured for voltage stabilizing or noise mitigating. For example, the first electronic component 2 may be a part of a power path. The first electronic component 2 may be or may include a capacitor.

The first electronic component 2 has a first surface 21 and a second surface 22 opposite to the first surface 21, and includes a first conductive via 24. For example, the first electronic component 2 includes a main body 20, an electrical element (e.g., a deep trench capacitor (DTC) 25), a first dielectric layer 26, a circuit structure 27, a conductive pad 28, a second dielectric layer 29 and a conductive structure 23.

The main body 20 has a first surface 201 and a second surface 202 opposite to the first surface 201. A material of the main body 20 may be silicon or glass. The second surface 22 of the first electronic component 2 may be the second surface 202 of the main body 20. The first conductive via 24 extends through the main body 20 from the first surface 201 to the second surface 202. The first conductive via 24 may have a first surface 241 and a second surface 242 opposite to the first surface 241. The first surface 241 may be substantially coplanar with, or aligned with, the first surface 201 of the main body 20. The second surface 242 may be substantially coplanar with, or aligned with, the second surface 201 of the main body 20 and the second surface 22 of the first electronic component 2. In other words, the second surface 242 of the first conductive via 24 is exposed from the second surface 22 of the first electronic component 2. The first conductive via 24 may include a conductive portion and an insulation layer. The insulation layer may surround or be disposed at a periphery of the conductive portion. In some embodiments, the insulation layer may be omitted.

The electrical element (e.g., the DTC 25) is embedded in the main body 20, and a portion of the electrical element (e.g., the DTC 25) may be exposed from the main body 20. In some embodiments, the electrical element (e.g., the DTC 25) is disposed adjacent to the first surface 21 of the first electronic component 2. Thus, the first surface 21 of the first electronic component 2 may be an active surface or a functional surface, and the second surface 22 of the first electronic component 2 may be a backside surface or a non-functional surface. In some embodiments, the electrical element may be a transistor, resistor, transducer or other element.

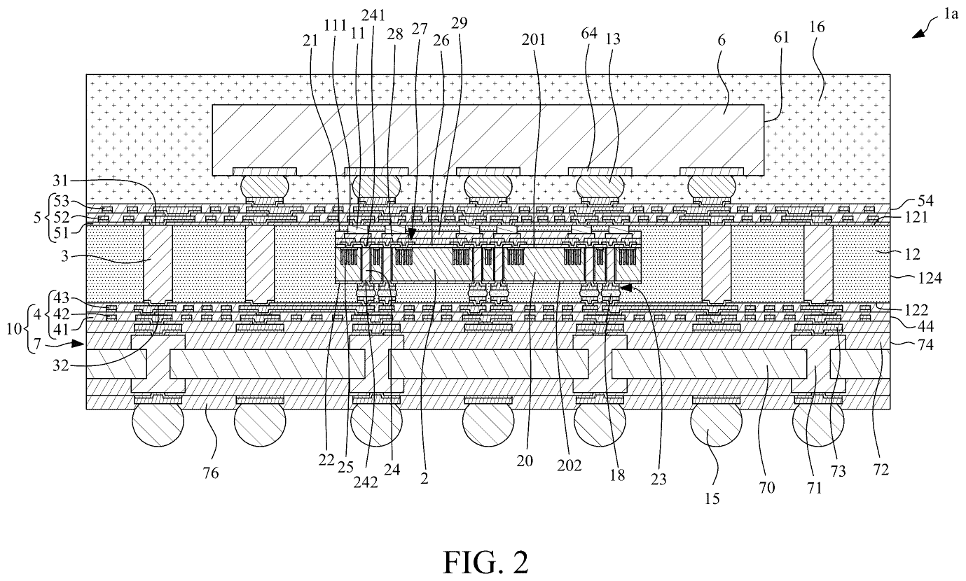

The first dielectric layer 26 is disposed on the first surface 201 of the main body 20. The circuit structure 27 is disposed on the first dielectric layer 26. The circuit structure 27 may be a back end of line (BEOL). The circuit structure 27 may include a conductive layer and a passivation layer disposed thereon. Portions of the circuit structure 27 extend through the first dielectric layer 26 to contact and electrically connect the first conductive via 24 and the DTC 25. In some embodiments, the circuit structure 27 may include more than one conductive layers and more than one passivation layers. The conductive pad 28 is disposed on and configured to electrically connect the circuit structure 27. For example, a portion of the conductive pad 28 extends through the passivation layer to contact the conductive layer. In some embodiments, the first electronic component 2 may include a plurality of DTCs 25, each DTC 25 may include a positive electrode and a negative electrode. The circuit structure 27 may include a first portion electrically connected to the positive electrode of each of the DTCs 25, and a second portion electrically connected to the negative electrode of each of the DTCs 25. The first electronic component 2 may also include two conductive pads corresponding to the two portions of the circuit structure 27. The cross section of the electronic device 1 in FIG. 1 merely shows one portion of the circuit structure 27 and one conductive pad 28 of the first electronic component 2 corresponding to the positive electrode or the negative electrode of each DTC 25. Another cross section of the electronic device 1 (similar to that shown in FIG. 2) may show two portions of the circuit structure 27 and two conductive pads 28 of the first electronic component 2 corresponding to both the positive electrode and the negative electrode of each DTC 25. The second dielectric layer 29 is disposed on and covers the circuit structure 27 and at least a portion of the conductive pad 28. In some embodiments, the first electronic component 2 may further include an interconnection element 11 disposed on and configured to electrically connect the conductive pad 28.

The conductive structure 23 is disposed on the second surface 202 of the main body 20 and is configured to electrically connect the first conductive via 24. The conductive structure 23 may include a dielectric layer, a seed layer and a conductive layer. The seed layer and the conductive layer may serve as a bump pad for electrical connection. A solder material 18 is disposed on the conductive structure 23, and is configured to electrically connect the first electronic component 2 to the first conductive structure 4.

The conductive element 3 is disposed on the first conductive structure 4 and adjacent to the first electronic component 2. The conductive element 3 has a first surface 31 and a second surface 32 opposite to the first surface 31. The second surface 32 may contact the first conductive structure 4 of the first wiring structure 10. In some embodiments, the electronic device 1 may include a plurality of the conductive elements 3. The conductive elements 3 may surround the first electronic component 2. In some embodiments, the conductive element 3 may be a conductive pillar.

The first encapsulant 12 is disposed on the first wiring structure 10, and encapsulates the first electronic component 2 and the conductive element 3. For example, the first encapsulant 12 may be disposed on the first conductive structure 4 of the first wiring structure 10. The first encapsulant 12 may be formed of a molding compound with or without fillers. The first encapsulant 12 has a first surface 121, a second surface 122 opposite to the first surface 121, and a lateral surface 124 extending between the first surface 121 and the second surface 122. The second surface 122 contacts the first conductive structure 4. A top surface 111 of the interconnection element 11 of the first electronic component 2, a top surface (e.g., the first surface 31) of the conductive element 3 and a top surface (e.g., the first surface 121) of the encapsulant 12 are substantially coplanar with, or aligned with, each other. The lateral surface 124 of the first encapsulant 12 is substantially coplanar with, or aligned with, a lateral surface 44 of the first conductive structure 4 and a lateral surface 74 of the second conductive structure 7. A portion of the first encapsulant 12 may be interposed between the second surface 22 of the first electronic component 2 and the first conductive structure 4. Thus, the first encapsulant 12 may cover and contact the second surface 22 of the first electronic component 2.

The second electronic component 6 is disposed over the first electronic component 2, and is physically separated from the encapsulant 12. A lateral surface 124 of the encapsulant 12 is misaligned with, or not coplanar with, a lateral surface 61 of the second electronic component 6. For example, the second electronic component 6 may cover the first electronic component 2 and physically separated from the conductive element 3. The first electronic component 2 is disposed between the second electronic component 6 and the first wiring structure 10. The second electronic component 6 is electrically connected to the conductive element 3 and configured to receive a power from the first electronic component 2. In some embodiments, the second electronic component 6 may be an active component such as a semiconductor die. The second electronic component 6 is electrically connected to the first electronic component 2 and the conductive element 3. In other words, the conductive element 3 is electrically connected to the second electronic component 6. In some embodiments, the second electronic component 6 is electrically connected to the first wiring structure 10 through the first electronic component 2. The conductive element 3 extends through the first encapsulant 12 to electrically connect the second electronic component 6 and the first conductive structure 4 of the first wiring structure 10. For example, the second electronic component 6 may include a plurality of bump pads 64, and the bump pads 64 may be electrically connected to the first electronic component 2 and the conductive element 3 through a plurality of solder materials 13. In some embodiments, the electronic device 1 is configured to provide a signal path passing through the first electronic component 2. For example, the signal path may pass in a vertical direction through the first electronic component 2. T he signal path may be between the second electronic component 6 and the first wiring structure 10. The first wiring structure 10 (e.g., the first conductive structure 4 and/or the second conductive structure 7 of the first wiring structure 10) extends beyond a lateral surface 61 of the second electronic component 6. That is, a width of the first wiring structure 10 is greater than a width of the second electronic component 6. A functional surface (e.g., the first surface 21) of the first electronic component 2 faces the second electronic component 6.

The second encapsulant 16 is disposed on the first surface 121 of the first encapsulant 12 and encapsulates the second electronic component 6 and the solder materials 13. In some embodiments, the second encapsulant 16 may be formed of a molding compound with or without fillers.

In the electronic device 1 of the present disclosure, since the second electronic component 6 is disposed after the conductive element 3 and the first encapsulant 12, the yield of the second electronic component 6 may not be affected by formation of the conductive element 3 and molding/grinding process of the first encapsulant 12. Besides, since the first wiring structure 10 is not formed on the second electronic component 6, an area of the first wiring structure 10 is not limited by the size of the second electronic component 6.

FIG. 2 illustrates a cross sectional view of a device 1a according to some embodiments of the present disclosure. The electronic device 1a is similar to the electronic device 1 shown in FIG. 1, except that the electronic device 1a further includes a second wiring structure 5. In some embodiments, the second wiring structure 5 may be referred as a first wiring structure.

As shown in FIG. 2, the second wiring structure 5 is disposed on the first encapsulant 12 and electrically connected to the first electronic component 2 and the conductive element 3. The second electronic component 6 is disposed on and electrically connected to the second wiring structure 5. That is, the first electronic component 2 is electrically connected to the second electronic component 6 through the second wiring structure 5. The second wiring structure 5 is configured to electrically connect the first electronic component 2 and the conductive elements 3 to the second electronic component 6. A lateral surface 54 of the second wiring structure 5 is misaligned with, or not coplanar with, a lateral surface 61 of the second electronic component 6.

The second wiring structure 5 may include at least one dielectric layer 51, at least one circuit pattern layer (e.g., a circuit pattern layers 52 and an additional circuit pattern layer 53). However, the amount of the dielectric layer 51 and the amount of the circuit pattern layers 52, 53 are not limited in the present disclosure. The dielectric layer 51 may be disposed on the first encapsulant 12. The circuit pattern layer 52 may be disposed on and extend through the dielectric layer 51 to electrically connect and/or contact the conductive element 3 and the first electronic component 2. Another dielectric layer 51 may be disposed on and cover the circuit pattern layer 52. The additional circuit pattern layer 53 and still another dielectric layer 51 may be sequentially disposed on the circuit pattern layer 52 in a similar manner. The circuit pattern layer 52 and/or the additional circuit pattern layer 53 may include a seed layer and a conductive layer. In some embodiments, the seed layer may be omitted. The circuit pattern layer 52 and/or the additional circuit pattern layer 53 may include a conductive pad and/or a conductive trace. As shown in FIG. 2, the electronic device 1a may include a plurality of conductive elements 3. At least one of the conductive elements 3 may be uncovered by the second electronic component 6. In other words, at least one of the conductive elements 3 is not disposed right under the second electronic component 6.

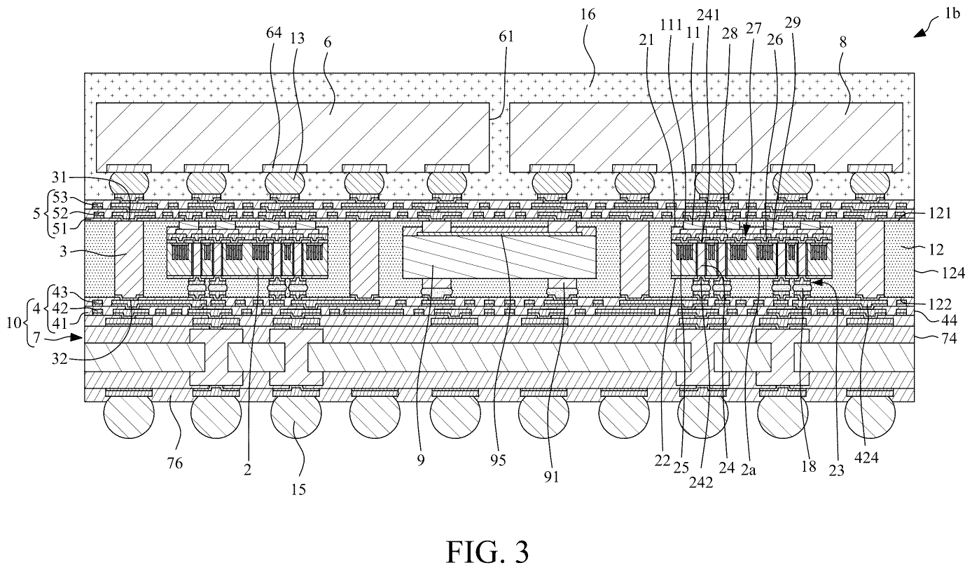

FIG. 3 illustrates a cross sectional view of an electronic device 1b according to some embodiments of the present disclosure. The electronic device 1b is similar to the electronic device 1a shown in FIG. 2, except that the electronic device 1b includes two passive element (e.g., a first electronic component 2 and a first additional electronic component 2a) and two electronic component (e.g., a second electronic component 6 and a fourth electronic component 8), and further includes a third electronic component 9.

The first electronic component 2 and the first additional electronic component 2a are the same as that described according to FIG. 1. The first electronic component 2 and the first additional electronic component 2a are disposed on and electrically connected to the first conductive structure 4.

The third electronic component 9 is also disposed on the first conductive structure 4, and may be disposed between the first electronic component 2 and the first additional electronic component 2a. The third electronic component 9 may be a bridge die. In some embodiments, the third electronic component 9 may further include a capacitor. The third electronic component 9 includes a pad 91 (e.g., a dummy pad) disposed adjacent to and connected to the first wiring structure 10, and a redistribution layer 95 disposed adjacent to a top surface of the third electronic component 9. Due to the arrangement of the dummy pad 91, the third electronic component 9 can be properly positioned on the first conductive structure 4. However, in other embodiments, the third electronic component 9 may be adhered to the first conductive structure 4 by an adhesive layer. The first encapsulant 12 is disposed on the first conductive structure 4 of the first wiring structure 10, and encapsulates the first electronic component 2, the first additional electronic component 2a and the third electronic component 9. The second wiring structure 5 is disposed on the first encapsulant 12 and electrically connected to the first electronic component 2, the first additional electronic component 2a and the third electronic component 9.

The second electronic component 6 is the same as that described according to FIG. 1. The second electronic component 6 is disposed on the second wiring structure 5, and electrically connected to the first electronic component 2, the conductive element 3 and the third electronic component 9. The second electronic component 6 is separated from the first wiring structure 10 by the third electronic component 9. For example, the second electronic component 6 may be disposed right above the first electronic component 2.

The fourth electronic component 8 is disposed side-by-side with, or adjacent to, the second electronic component 6. The fourth electronic component 8 may be electrically connected to the second electronic component 6 through the third electronic component 9. The fourth electronic component 8 is also disposed on the second wiring structure 5, and electrically connected to the first additional electronic component 2a, the conductive element 3 and the third electronic component 9. That is, the third electronic component 9 electrically connects the second electronic component 6 and the fourth electronic component 8. A signal from the second electronic component 6 may pass through the redistribution layer 95 of the third electronic component 9 to reach the fourth electronic component 8. The fourth electronic component 8 may be disposed right above the first additional electronic component 2a. A signal path between the fourth electronic component 8 and the first conductive structure 4 passes through the second first electronic component 2a. In some embodiments, the second electronic component 6 and the fourth electronic component 8 may both be semiconductor dice, but with different functions.

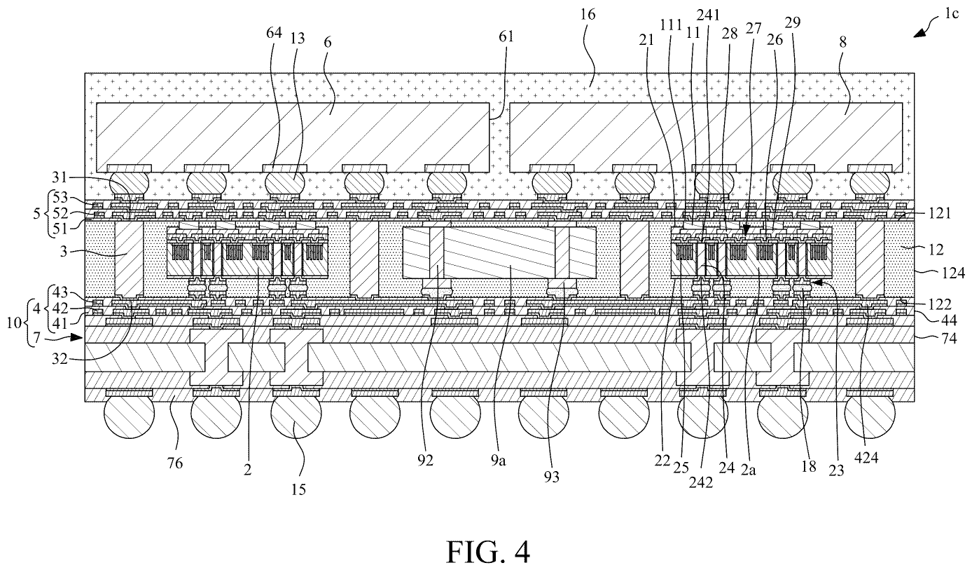

FIG. 4 illustrates a cross sectional view of an electronic device 1c according to some embodiments of the present disclosure. The electronic device 1c is similar to the electronic device 1b shown in FIG. 3, except that the third electronic component 9a in the electronic device 1c further includes a plurality of through vias 92 extending through the third electronic component 9a. Besides, instead of the dummy pad 91 in the third electronic component 9, the third electronic component 9a includes at least one pad 93 (e.g., conductive pad) electrically connected to the first wiring structure 10. Due to the arrangement of the through vias 92 and the conductive pad 93, a signal path may extend through the third electronic component 9 in a vertical direction parallel with a direction from the second electronic component 6 to the first conductive structure 4. The second electronic component 6 and/or the fourth electronic component 8 is electrically connected to the first wiring structure 10 through the conductive pad 91 of the third electronic component 9.

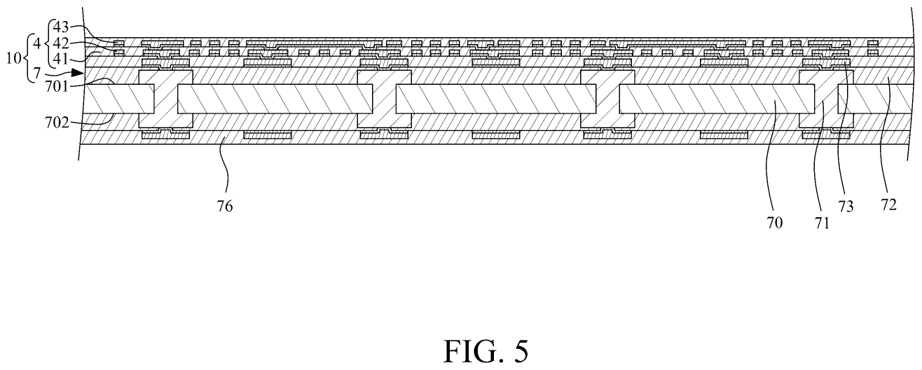

FIG. 5 through FIG. 9 illustrate a method for manufacturing an electronic device according to some embodiments of the present disclosure. In some embodiments, the method is for manufacturing the electronic device 1 shown in FIG. 1.

Referring to FIG. 5, a first wiring structure 10 is provided. The first wiring structure 10 may include a first conductive structure 4 and a second conductive structure 7. The second conductive structure 7 may include a core substrate 70. Since the first wiring structure 10 has sufficient structural strength, a carrier may not be necessary for supporting the first wiring structure 10.

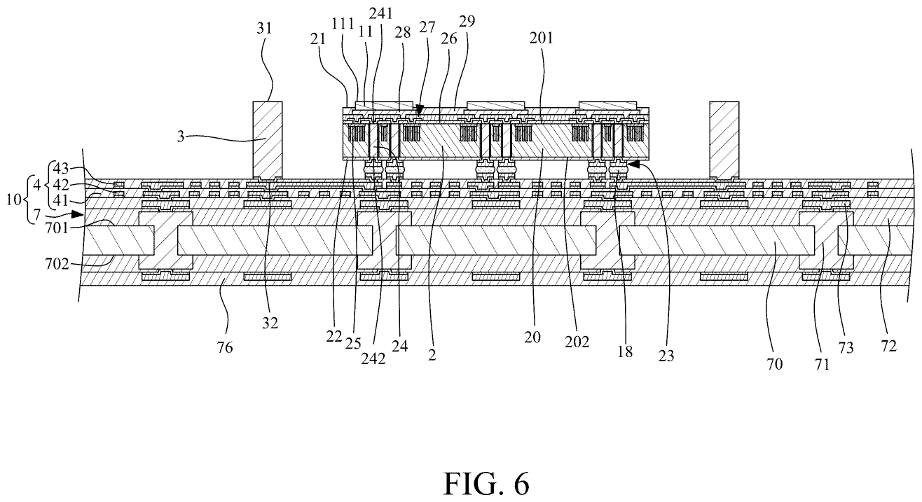

Referring to FIG. 6, a first electronic component 2 and at least one conductive element 3 are formed or disposed on and electrically connected to the first wiring structure 10, such as the first conductive structure 4 of the first wiring structure 10. Preferably, the conductive element 3 is formed or disposed on the first wiring structure 10 before disposing the first electronic component 2.

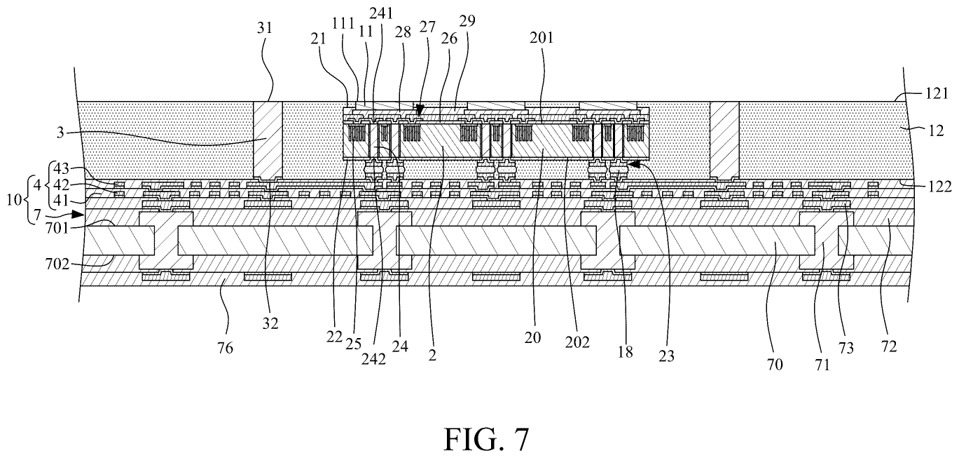

Referring to FIG. 7, a first encapsulant 12 is formed or disposed on the first wiring structure 10 to encapsulate the first electronic component 2 and the conductive element 3. In some embodiments, the first encapsulant 12 may cover a top surface 111 of an interconnection element 11 of the first electronic component 2 and a top surface (e.g., a first surface 31) of the conductive element 3. Then, a grinding process may be conducted to the first encapsulant 12 to expose the first electronic component 2 and the conductive element 3, thus the top surface 111 of the interconnection element 11 of the first electronic component 2, the top surface (e.g., the first surface 31) of the conductive element 3 and a top surface (e.g., the first surface 121) of the encapsulant 12 are substantially coplanar with, or aligned with, each other.

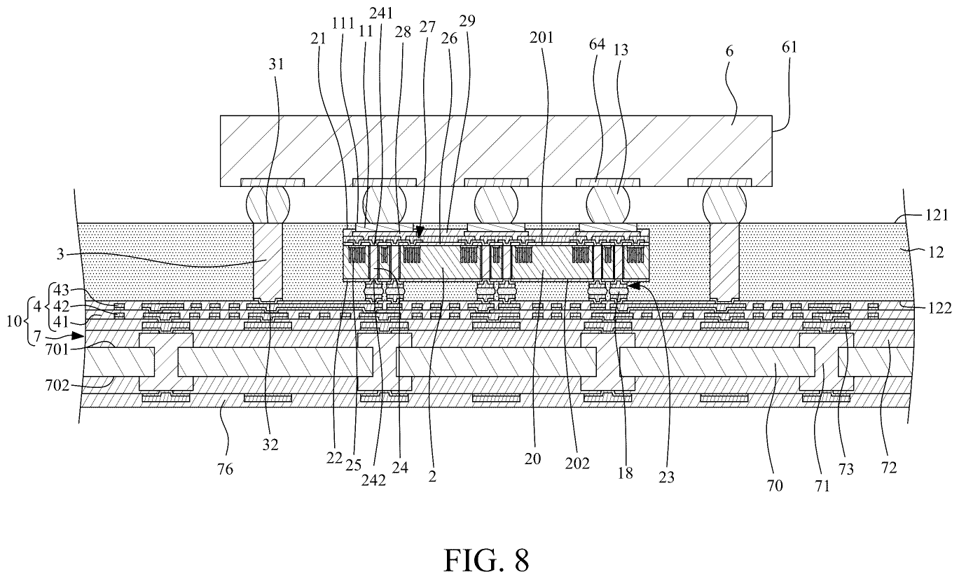

Referring to FIG. 8, a second electronic component 6 is disposed on the first encapsulant 12, and is electrically connected to the first electronic component 2 and the conductive element 3.

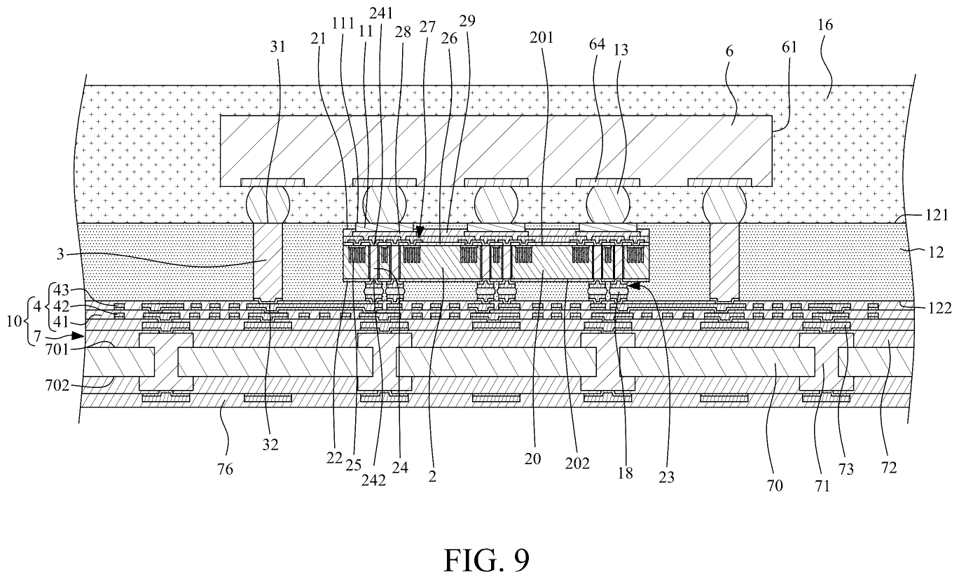

Referring to FIG. 9, a second encapsulant 16 is formed on the first encapsulant 12 to encapsulate the second electronic component 6. Then, at least one external connector 15 is formed or disposed on the first wiring structure 10, such as the second conductive structure 7 of the first wiring structure 10. Then, a singulation process is conducted to form the electronic device 1 as shown in FIG. 1.

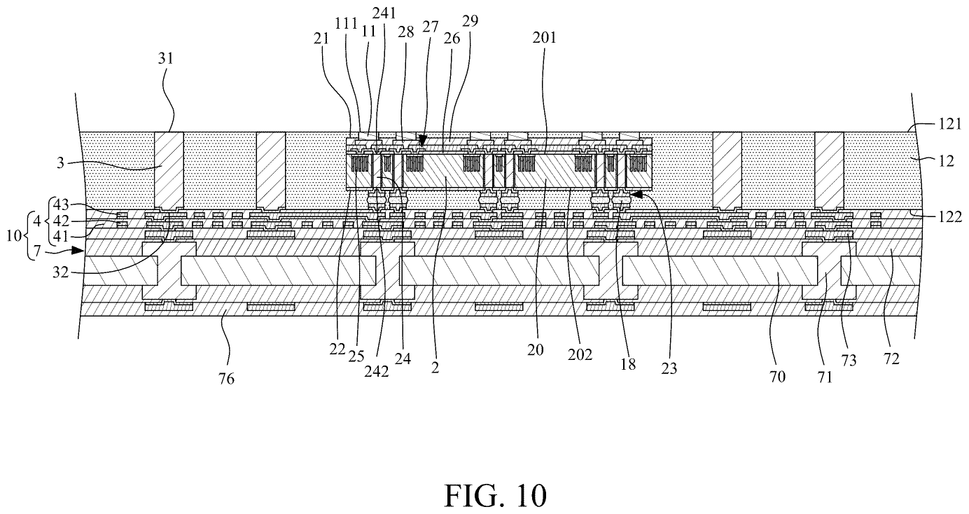

FIGS. 10 through 13 illustrate a method for manufacturing an electronic device according to some embodiments of the present disclosure. In some embodiments, the method is for manufacturing the electronic device 1a shown in FIG. 2. The initial stages of the illustrated process are the same as, or similar to, the stages illustrated in FIG. 5 through FIG. 6. FIG. 10 depicts a stage subsequent to that depicted in FIG. 6.

Referring to FIG. 10, similar to FIG. 7, a first encapsulant 12 is formed on the first wiring structure 7 to encapsulate the first electronic component 2 and the conductive element 3.

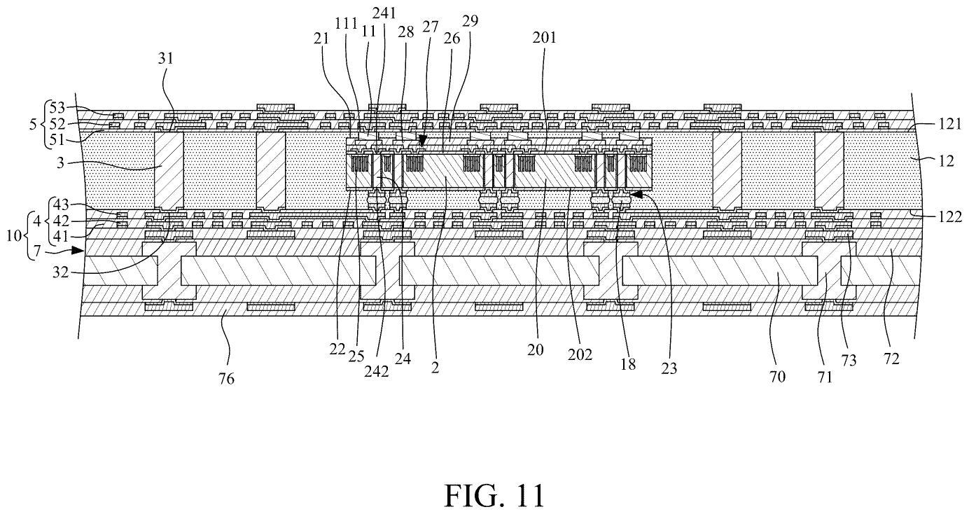

Referring to FIG. 11, a second wiring structure 5 is formed on the first encapsulant 12 and is electrically connected to the first electronic component 2 and the conductive element 3.

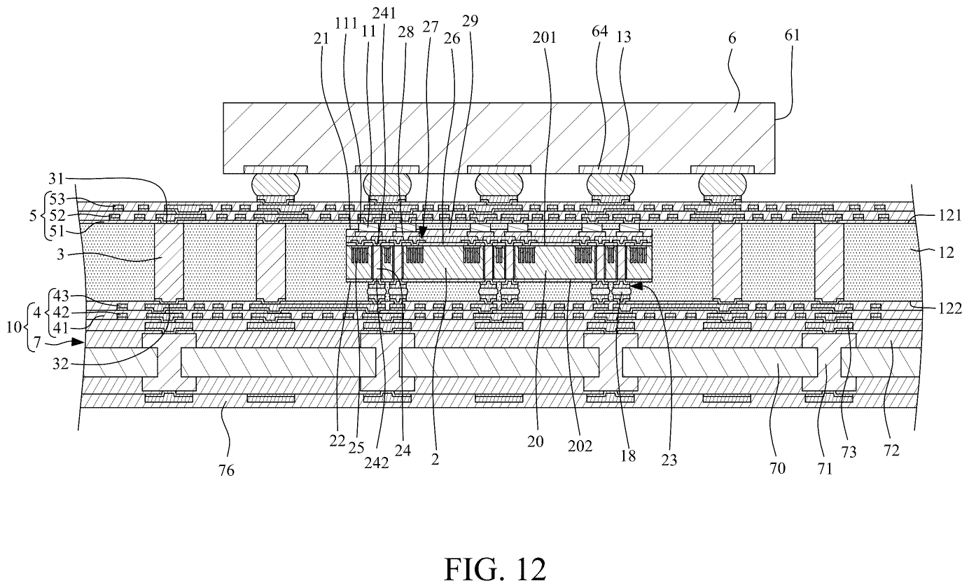

Referring to FIG. 12, a second electronic component 6 is disposed on and electrically connected to the second wiring structure 5, and is electrically connected to the first electronic component 2 and the conductive element 3 through the second wiring structure 5.

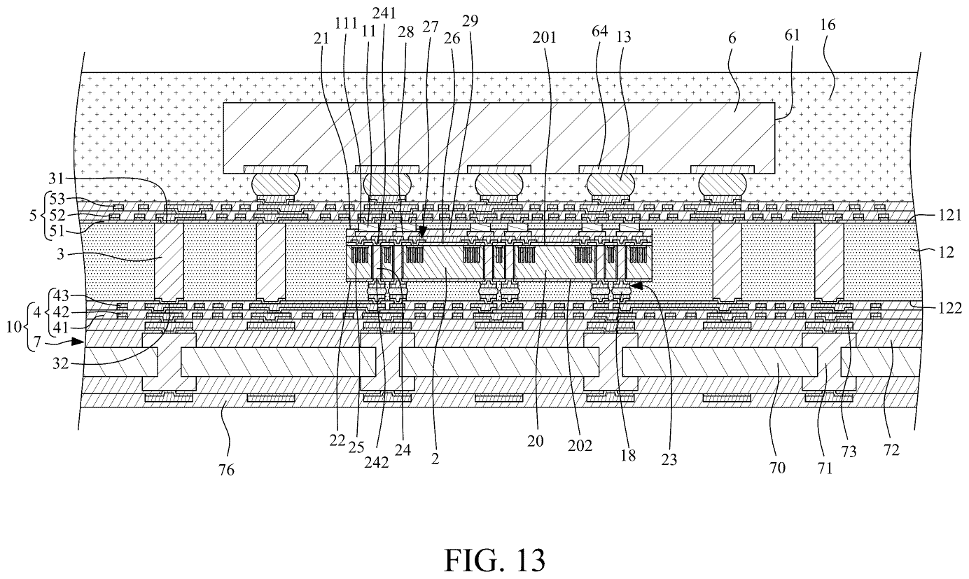

Referring to FIG. 13, a second encapsulant 16 is formed on the second wiring structure 5 to encapsulate the second electronic component 6. Then, a singulation process is conducted to form the electronic device 1a as shown in FIG. 2.

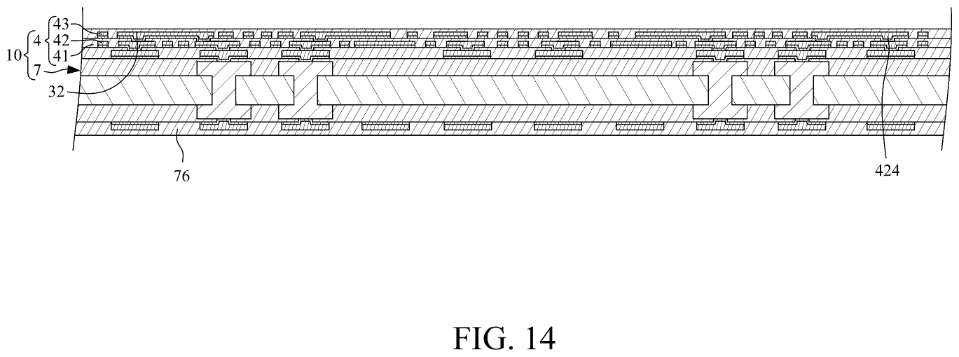

FIGS. 14 through 19 illustrate a method for manufacturing an electronic device according to some embodiments of the present disclosure. In some embodiments, the method is for manufacturing the electronic device 1b shown in FIG. 3.

Referring to FIG. 14, a first wiring structure 10 is provided. The first wiring structure 10 may include a first conductive structure 4 and a second conductive structure 7.

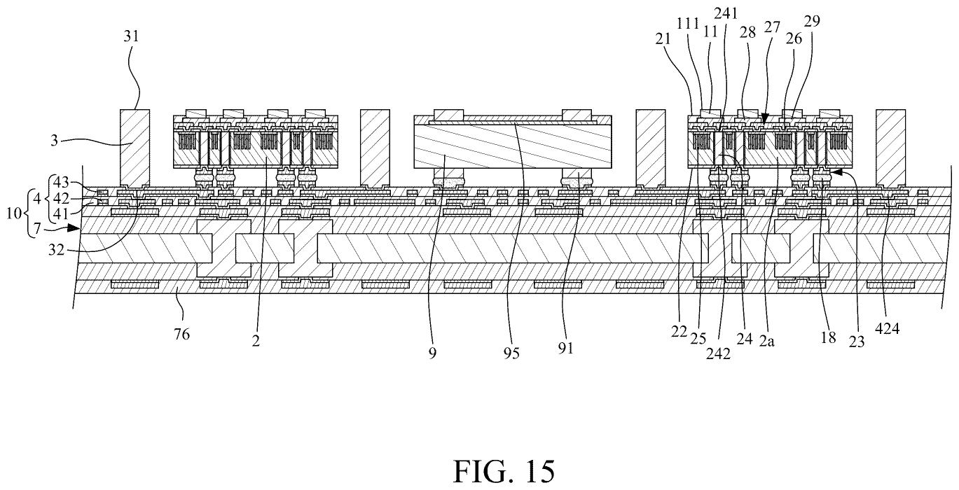

Referring to FIG. 15, a first electronic component 2, a third electronic component 9, a first additional component 2a and at least one conductive element 3 are formed or disposed on and electrically connected to the first wiring structure 10, such as the first conductive structure 4 of the first wiring structure 10. Preferably, the conductive element 3 is formed or disposed on the first wiring structure 10 before disposing the first electronic component 2, the third electronic component 9 and the first additional component 2a.

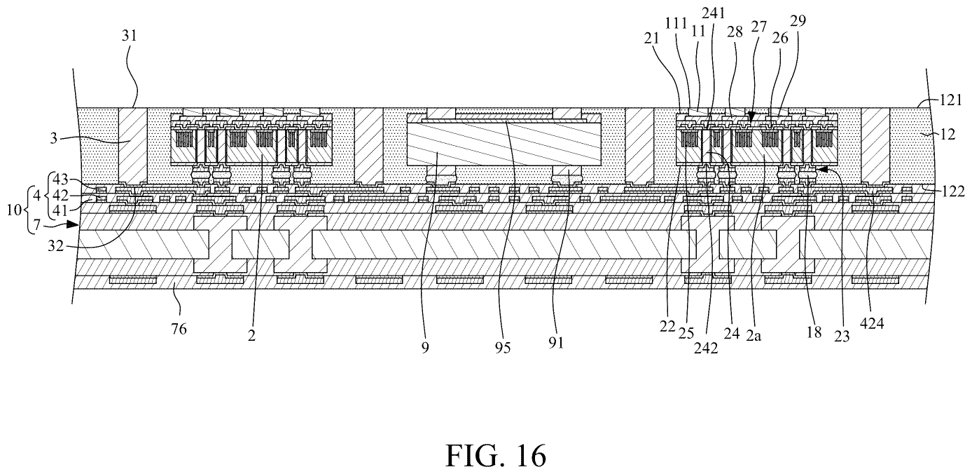

Referring to FIG. 16, a first encapsulant 12 is formed or disposed on the first wiring structure 10 to encapsulate the first electronic component 2, the third electronic component 9, the first additional component 2a and the conductive element 3.

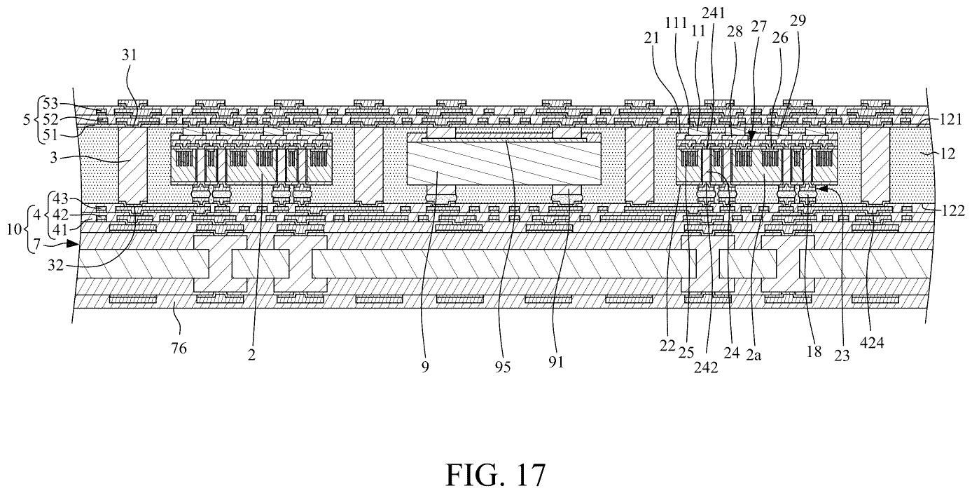

Referring to FIG. 17, a second wiring structure 5 is formed on the first encapsulant 12, and is electrically connected to the first electronic component 2, the third electronic component 9, the first additional component 2a and the conductive element 3.

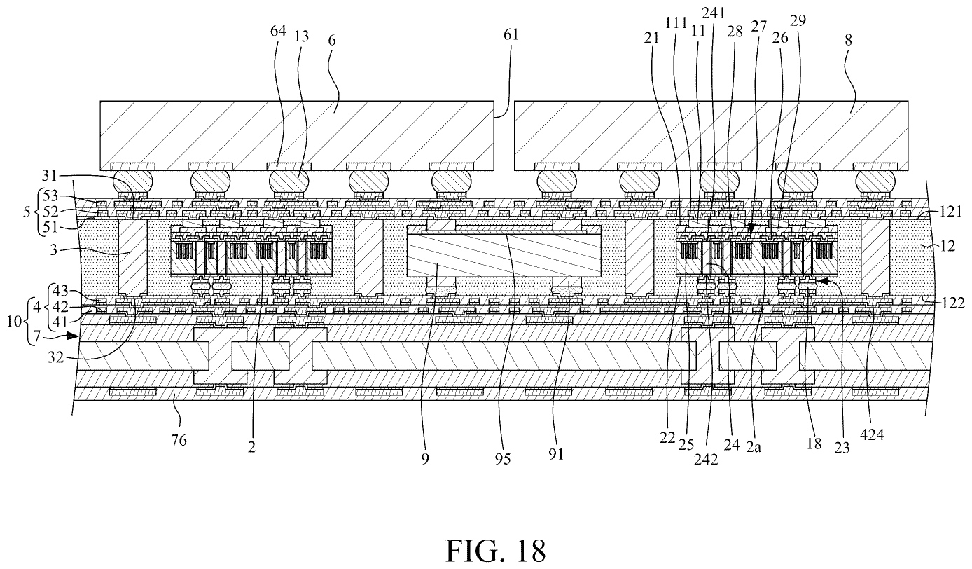

Referring to FIG. 18, a second electronic component 6 and the fourth electronic component 8 are disposed on and electrically connected to the second wiring 5, and is electrically connected to the first electronic component 2, the third electronic component 9, the first additional component 2a and the conductive element 3 through the second wiring structure 5.

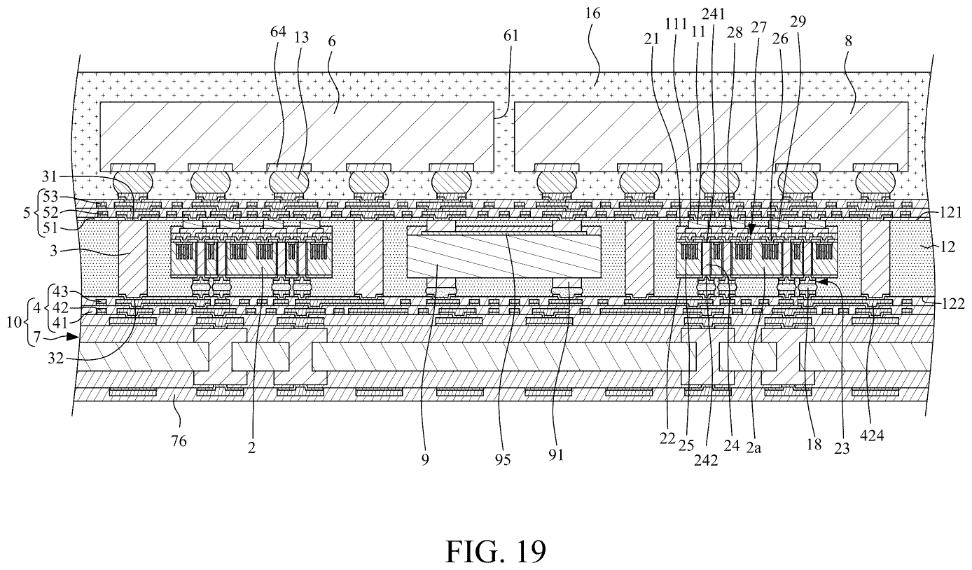

Referring to FIG. 19, a second encapsulant 16 is formed on the second wiring structure 5 to encapsulate the second electronic component 6 and the fourth electronic component 8). Then, a singulation process is conducted to form the electronic device 1b as shown in FIG. 3.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first electronic component having a top surface, a bottom surface opposite to the top surface, and a lateral surface extending between the top surface and the bottom surface;
a first molding compound encapsulating the first electronic component, wherein the first molding compound contacts the lateral surface, the top surface, and the bottom surface of the first electronic component;
at least one conductive element penetrating through the first molding compound and encapsulated by the first molding compound;
a second electronic component disposed over the first electronic component and spaced apart from the first molding compound, wherein the first electronic component is entirely disposed within a vertical projection of the second electronic component in a cross-sectional view, and the top surface of the first electronic component faces the second electronic component;
at least one first solder in direct contact with the second electronic component and the at least one conductive element; and
a second molding compound encapsulating the second electronic component and the at least one first solder, wherein the second molding compound is in direct contact with the first molding compound.

2. The electronic device of claim 1, further comprising a wiring structure disposed under the first molding compound and adjacent to the bottom surface of the first electronic component, wherein the wiring structure is electrically connected to the first electronic component and in direct contact with the at least one conductive element.

3. The electronic device of claim 2, wherein a lateral surface of the first molding compound, a lateral surface of the second molding compound and a lateral surface of the wiring structure are substantially coplanar with each other.

4. The electronic device of claim 3, wherein the lateral surface of the second molding compound is misaligned with a lateral surface of the second electronic component, and the second molding compound contacts the lateral surface of the second electronic component.

5. The electronic device of claim 4, wherein the wiring structure comprises a first circuit pattern layer and a second circuit pattern layer, the first circuit pattern layer is disposed between the first molding compound and the second circuit pattern layer, and a density of the first circuit pattern layer is greater than a density of the second circuit pattern layer.

6. The electronic device of claim 5, wherein the wiring structure further comprises a core substrate and a through via penetrating through the core substrate, and the second circuit pattern layer is electrically connected and disposed between the first circuit pattern layer and the through via.

7. The electronic device of claim 6, wherein the first electronic component comprises a main body and a conductive via penetrating through the main body, and the at least one first solder is disposed right above the conductive via.

8. The electronic device of claim 7, wherein the conductive via of the first electronic component is disposed right above the through via of the wiring structure.

9. The electronic device of claim 8, wherein the first electronic component further comprises a bump pad electrically connected to and in direct contact with the conductive via of the first electronic component, and the bump pad is electrically connected to the wiring structure through a second solder.

10. The electronic device of claim 9, wherein the first molding compound encapsulates and is in direct contact with the bump pad of the first electronic component and the second solder.

11. The electronic device of claim 2, wherein the first electronic component comprises at least one interconnection element, and a top surface of the at least one interconnection element of the first electronic component and a top surface of the at least one conductive element are substantially aligned with each other.

12. The electronic device of claim 11, wherein the at least one interconnection element comprises a plurality of interconnection elements, and the first molding compound extends into a space between adjacent two of the interconnection elements.

13. The electronic device of claim 12, wherein the first molding compound further extends into a space between the bottom surface of the first electronic component and a top surface of the wiring structure.

14. The electronic device of claim 1, wherein the first electronic component is a capacitor and configured for voltage stabilizing or noise mitigating.

15. The electronic device of claim 14, wherein the second electronic component is electrically connected to the conductive element and configured to receive a power from the first electronic component.

16. The electronic device of claim 15, wherein the first electronic component includes a deep trench capacitor.

17. The electronic device of claim 1, wherein the at least one conductive element comprises a plurality of conductive elements, and all of the conductive elements are disposed within a vertical projection of the second electronic component in a cross-sectional view.

18. An electronic device, comprising:
a first wiring structure;
a first electronic component disposed on the first wiring structure and comprising an interconnection element;
a conductive pillar disposed on and in direct contact with the first wiring structure;
a first molding compound encapsulating the first electronic component and the conductive pillar, wherein a top surface of the first molding compound, a top surface of the interconnection element of the first electronic component and a top surface of the conductive pillar are substantially aligned with each other;
a second electronic component disposed over the first electronic component and electrically connected to the first wiring structure through the first electronic component and the conductive pillar; and
a second molding compound directly on the top surface of the first molding compound, and encapsulating the second electronic component.

19. The electronic device of claim 18, further comprising:
a first solder electrically connected to and in direct contact with the second electronic component and the at least one interconnection element of the first electronic component; and
a second solder electrically connected to and in direct contact with the second electronic component and the conductive pillar.

20. The electronic device of claim 19, wherein an entire bottom surface of the second molding compound is in direct contact with the entire top surface of the first molding compound, wherein the second molding compound encapsulates the second electronic component, the first solder and the second solder.
